(19) United States
(12) Patent Application Publication
(10) Pub. No.: US 2009/0260675 A1
(43) Pub. Date: Oct. 22, 2009

(54) ENCAPSULATION OF SOLAR MODULES

(76) Inventors: Serkan Erdemli, San Jose, CA (US); Burak Metin, Milpitas, CA (US)

Correspondence Address: PILLSBURY WINTHROP SHAW PITTMAN LLP, P.O. BOX 10500, MCLEAN, VA, 22102, US

(21) Appl. No.: 12/106,210

(22) Filed: Apr. 18, 2008

(51) Int. Cl. H01L 31/042

(52) U.S. Cl. 136/251

(57) ABSTRACT

A method for encapsulating interconnected solar cells including Group IBIIIAVIA absorbers and an apparatus according to the same, whereby a light receiving side encapsulant layer including thermoplastic polyurethane is used to cover the light receiving sides of the interconnected solar cells. The back sides of the interconnected solar cells are covered with a back side encapsulant layer that is different from the light receiving side encapsulant layer.

### BACKGROUND

1. Field of the Invention

The present invention generally relates to solar module design and fabrication and, more particularly, to packaging techniques for solar modules such as solar modules employing Group IBIIIAVIA absorbers.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which comprises a material in the family of Cu(In,Ga,Al)(S,Se,Te)₂, is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers comprising Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

Manufactured solar cells are interconnected by stringing them or shingling them to form solar modules. Such modules are constructed using various packaging materials to mechanically support and to protect the solar cells against environmental degradation. The most common packaging technology involves lamination of solar cell strings or circuits in transparent encapsulants. In a lamination process, in general, electrically interconnected solar cells are sandwiched between layers of encapsulants and front and back protective sheets; and all the components are subjected to heat and pressure to bond module components together forming a module package. The front protective sheet is typically glass, but may also be a transparent flexible polymer film such as TEFZEL® The back protective sheet may be a sheet of glass or a polymeric sheet such as TEDLAR®. Light enters the module through the front protective sheet.

A variety of materials are used as encapsulants for packaging solar cell modules, such as ethylene vinyl acetate copolymer (EVA). Although EVA is typically the best known encapsulant material in the solar cell industry, it has certain limitations. One well known limitation of EVA is its decomposition under sunlight and moisture from prolonged use, which results in releasing of acetic acid. Acetic acid production and glass transition concerns with ethylene-vinyl acetate used in photovoltaic devices, Michael D. Kempe; Gary J. Jorgensen; Kent M. Terwilliger; Tom J. McMahon; Cheryl E. Kennedy; Theodore T. Borek, Solar Energy Materials and Solar Cells, Volume 91, Issue 4, 15 Feb. 2007, Pages 315-329) (Applications of Ethylene Vinyl Acetate as an Encapsulation Material for Terrestrial Photovoltaic Modules, E. F. Cuddihy. C.D. Coulbert, R. H. Liang, A. Gupta, P. Willis, B. Baum, DOE/JPL/1012-87,) Acetic acid is especially harmful for thin film solar cell structures employing CIGS absorbers. Lamination of solar cells using EVA as the encapsulant leaves unreacted peroxides even after obtaining very high gel contents. Unreacted peroxides may catalyze the discoloration of the EVA layers and corrosion of the solar cells throughout the lifetime of the solar module. Under the influence of acetic acid and unreacted chemicals, the CIGS absorber and other layers of the solar cell such as the transparent conductive oxide layer, the buffer layer such as Cd(Zn)S, etc. may degrade which in turn may lead to degradation, discoloration and eventually malfunction of the module.

A recently marketed thermoplastic material known as thermoplastic polyurethane (TPU) is one of the promising materials without the aforementioned shortcomings of EVA. Etimex, an encapsulant supplier from Germany, is presently offering a photovoltaic-grade TPU film. Lamination of TPU film does not involve incomplete curing reactions that would leave unreacted peroxides inside the laminated solar panel. For TPU, there is also no acetic acid generation during the lamination process or later upon exposure to sunlight and moisture, therefore it may be used as a substitute for EVA in the module structure. However, very high cost of TPU (almost double or triple the price of EVA) limits its use in the conventional manner of laminating solar cells, and as such there is a strong reason not to use it.

From the foregoing, there is a need in the solar cell manufacturing industry, especially in thin film photovoltaics, for better packaging techniques that can provide reliable performance at reduced cost. It should be noted that thin film technologies such as CIGS photovoltaics are being developed for cost reduction and they are very sensitive to the cost of module packaging.

### SUMMARY OF THE INVENTION

Present invention provides a method for encapsulating interconnected solar cells including Group IBIIIAVIA absorbers and an apparatus according to the same, whereby a light receiving side encapsulant layer including a thermoplastic polyurethane is used to cover the light receiving side of the interconnected solar cells. The back side of the interconnected solar cells are covered with a back side encapsulant layer that is different from the light receiving side encapsulant layer.

### DESCRIPTION OF THE DRAWINGS

FIG. 1 is a schematic view a solar cell;

FIG. 2 is a schematic view of components of a solar cell module of the present invention before an encapsulation process; and

FIG. 3 is a schematic view of the solar cell module shown in FIG. 2 after the encapsulation process.

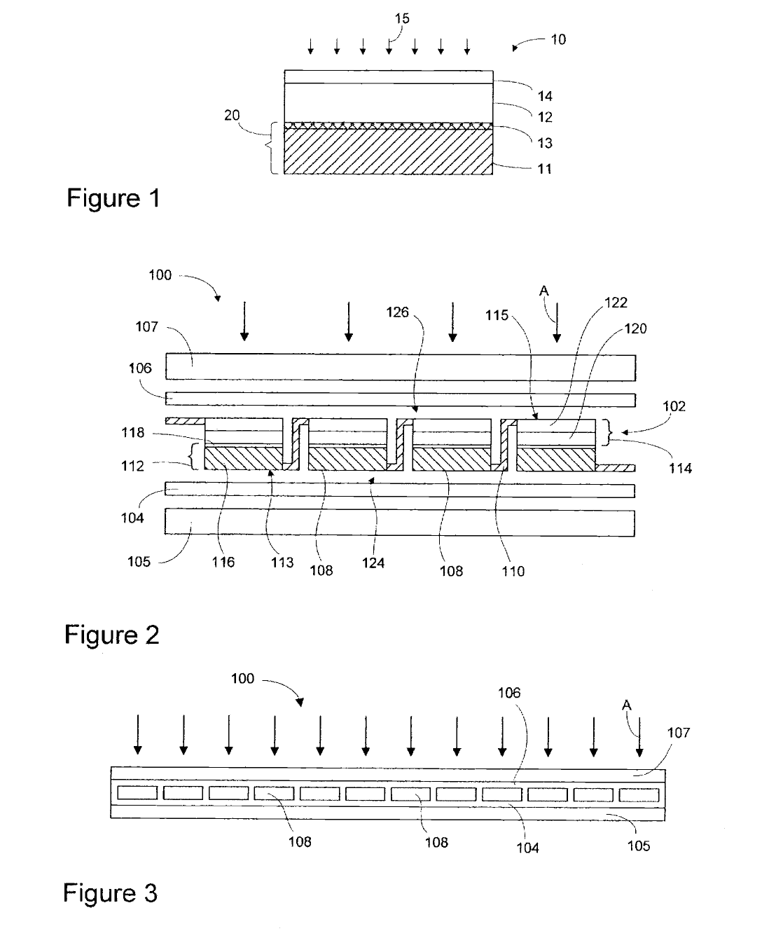

### DETAILED DESCRIPTION OF THE INVENTION

Present invention provides a packaging method for manufacturing IBIIIAVIA solar cell modules using a combination of more than one type of encapsulants to cover the front and back of the solar cells within the module to obtain a synergistic advantage in combination with reduced packaging cost and increased module lifetime. In one embodiment, a solar cell module having one or more solar cells may be encapsulated using at least two different layers of encapsulant materials. Accordingly, back of the interconnected solar cells within the module structure, which would not be exposed to light and its degrading affects, can be covered with a first material layer that is low cost and soft therefore providing a low-stress cushion for the devices. The first material may or may not be a transparent material. A front side of the interconnected solar cells, where the light is received, may be covered with a second material layer which is a transparent material layer that does not release harmful chemicals during lamination and is not prone to chemical degradation when exposed to light although it may be a higher cost material. In one embodiment, light receiving side of the solar cells may be coated with a transparent polyurethane material layer such as thermoplastic polyurethane (TPU), and the back side of the solar cells may be coated with a copolymer material layer such as ethylene vinyl acetate (EVA).

FIG. 2 shows the stacked components of a solar cell module 100 of the present invention in expanded view. The solar cell module comprises a solar cell device 102 or circuit interposed between a first encapsulant layer 104 or back encapsulant layer and a second encapsulant layer 106 or front encapsulant layer. A thickness range for the back encapsulant layer may be 12-18 mills, preferably 12 mils, and for the front encapsulant layer 106 may be 20-25 mils, preferably 20 mils, as will be further explained. The solar cell device 102 may be a string of solar cells 108 which are electrically interconnected using conductive interconnects 110 by utilizing processes, such as soldering, that are well known. The module 100 may have a rectangular or any other geometrical shape, and thus the size of the encapsulant layers 104 and 106, and the distribution of the solar cells 108 are arranged accordingly. The module 100 may also include additional components such as a back protective sheet 105 or layer placed under the back encapsulant layer 104, and a front protective sheet 107 or layer which may be placed over the front encapsulant layer 106. The back protective sheet 105 may typically be a sheet of glass or a polymeric sheet such as TEDLAR®, or another polymeric material. The back protective sheet 105 may comprise stacked sheets comprising various material combinations that will be described more fully below. The front protective sheet 107 is typically a glass, but may also be a transparent flexible polymer film such as TEFZEL®, or another polymeric film. TEDLAR® and TEFZEL® are brand names of fluoropolymer materials from DuPont. TEDLAR® is polyvinyl fluoride (PVF), and TEFZEL® is ethylene tetrafluoroethylene (ETFE) fluoropolymer. It should be noted that the thicknesses of the components shown in FIG. 2 are not to scale.

As shown in FIG. 2, each solar cell 108 comprises a base portion 112 having a back surface 113 and a front portion 114 having a front surface 115. The base portion 112 includes a substrate 116 and a contact layer 118 formed on the substrate. A preferred substrate material may be a metallic material such as stainless steel, aluminum or the like. An exemplary contact layer material may be molybdenum. The front portion 114 may comprise an absorber layer 120, such as a CIGS absorber layer which is formed on the contact layer 118, and a transparent layer 122, such as a buffer-layer/ZnO stack, formed on the absorber layer. An exemplary buffer layer may be a (Cd,Zn)S layer. Conductive fingers (not shown) may be formed over the transparent layer 122. Each interconnect 110 electrically connects the substrate 116 or the contact layer 118 of one of the cells to the transparent layer of the next cell, preferably in the manner shown in FIG. 2. However, the solar cells 108 may be interconnected using any other method known in the technology.

In the solar cell device 102, the base portions 112 of the solar cells 108 form the back side 124 of the solar cell device and likewise front portions 114 of the solar cells 108 form the front side 126 or the light receiving side of the solar cell device. Direction of the incoming light is depicted by arrows A. Furthermore, surface area of the front side 126, i.e., a combination of the areas of the front surfaces 115, forms the front surface or light receiving surface of the solar cell device, and similarly the surface area of the back side, i.e., a combination of areas of the back surfaces 113, forms the back surface of the solar cell device 102. Back surface and the front surface of the solar cell device 102 may include insulation spaces among the solar cells 102. As will be described more fully below, using a packaging process such as a lamination process, the back encapsulant layer 104 is coated over the back side 124, and the front encapsulant layer 106 is coated over the front side 126, entirely sealing the solar cell device 102, as shown in FIG. 3.

As mentioned above, the packaging method of the invention advantageously uses different materials as encapsulants to coat the backside 124 and the front side 126 to minimize chemical incompatibility issues between the packaging materials and the solar cells as well as reducing the cost and increasing the solar cell and module stability, output and life time. Referring to FIG. 2, in this embodiment, the back encapsulant layer 104 and the front encapsulant layer 106 may comprise materials that are chemically compatible with the back and front side materials of the solar cells that they are covering or coating. In this context, chemical compatibility means that no cell-performance-degrading chemical reaction can occur between the solar cell components and the first encapsulant material and the chemicals that may form in time under the operating conditions of the module under the sun. The back encapsulant layer material may comprise a polymer material such as EVA copolymer, Poly vinyl butyrate (PVB), Surlyn®, Polyesters such as Polyethylene terephthalate (PET), and ethylene methyl acrylate (EMA). EVA, PVB, Surlyn® (a family of ethylene methacrylic acid E/MAA copolymers, in which part of the methacrylic acid is neutralized with metal ions such as zinc or sodium) and EMA are transparent or translucent materials. PET may be made transparent or opaque. In this embodiment, the back encapsulant layer 104 may preferably be EVA. As described before, EVA is not a well chemically-compatible material for the solar-cell materials, especially thin film compound materials such as (Cd,Zn)S, CdTe, CIGS and transparent conductive oxides, although it is a low cost material. However, EVA or another packaging material, which may or may not be a transparent material, may be used as a back-layer encapsulant to coat the back side of the solar cell device. The front-layer encapsulant material may preferably comprise thermoplastic polyurethane (TPU) material which is chemically compatible with the front side of the thin film solar cell materials. After the stack, shown in FIG. 2, is prepared, it is subjected to a laminating process in a commercially known laminating apparatus. In the laminating apparatus, heat and pressure is applied to the components of the stack to attach the encapsulant layers 104 and 106 to the solar cell device 102 and to the front and back protective sheets 107 and 105.

Referring back to FIG. 2, in an exemplary lamination process, initially the front encapsulation layer 106 (TPU in this embodiment) is placed on the front protective sheet 107 which is pre-cleaned. There may be a moisture barrier tape or hot melt around the edges of the front sheet 107. Then, the front side 126 of the solar cell device 102 (interconnected solar cell string) is placed on the front encapsulant layer 106. The back encapsulant layer 104 (EVA in this embodiment) is placed on the back side 124 of the solar cell device 102. Finally, the back sheet 105 is placed over the back encapsulant layer 104. As mentioned above the back protective sheet material may be glass or Tedlar. However, various stack configurations may also be used as a back protective sheet such as Tedlar/Aluminum(Al)/Tedlar, Tedlar/Al/PET(polyethylene teraphthalate)/primer, Tedlar/Al/PET/EVA, PVDF(Polyvinylidene Fluoride)/Al/PET/primer or Tedlar/PET/Tedlar, PET/Al/PET/Primer, PEN(polyethylene naphthalate)/Al/PET, Tedlar/SiOₓ/PET. Alternatively, adhesives may be used to provide better adhesion between the components of the above stack. The adhesives promote adhesion between organic-inorganic and organic-organic interfaces. Both EVA and TPU materials may comprise adhesion promoters (silane coupling agents) to provide crosslinking sites with other materials. For example, adhesion promoters like gamma-methacryloxy-propyl-trimethoxysilane (Dow Corning Z-6030), 3-aminopropyltriethoxysilane, bis(trimethoxysilylpropyl)amine (Silquest A-1170) would improve adhesion between EVA and TPU layers, and also among encapsulants, front and back protective sheets. Other adhesion promoters may be other amino, diamino, vinyl, epoxy, and urethane silanes.

Such stacked components of the solar cell module are placed in a laminator and heat treated for about 10-20 minutes in a temperature range of 120°-160° C. The laminator may be a clamp-type laminator or it may be a roll-to-roll laminator. The clamp-type laminator may contain upper and lower chambers, and a rubbery diaphragm. The stacked components of the solar cell module will be placed on a heating plate in the lower chamber at a temperature range of 120°-160° C. During the lamination process, the upper and lower chambers are de-aired (vacuum) to 0.1-10 mbar pressure level in 3-20 seconds and kept at this pressure level for 3-7 minutes. The process de-airs and melts the front encapsulate and the back encapsulant around the solar cell device 102. After the melting step, the upper chamber pressure will be brought up to atmospheric pressure in several seconds while the lower chamber pressure will be kept at its previous pressure level. This step will apply pressure to the stacked components by the diaphragm and last 7-13 minutes to complete a uniform, bubble-free solar cell lamination. The lamination process yields a packaged solar cell module as shown in FIG. 3. The back encapsulant layer 104 coats the back side of the solar cell device 102 and the front encapsulant layer 106 coats the front side of the solar cell device. Prior art packages that seal solar cell modules with EVA material (EVA at the top and bottom of cell circuits) produce a large quantity of residual chemicals left in the sealed module because of the cross-linking (curing chemistry) nature of EVA. These chemicals remaining in the package for 20-25 years is a source of failure due to their corrosive, discoloring and delaminating affects, since the chemical and photochemical reactions continue under sunlight and moisture, and are accelerated by light. Therefore, under sunlight, the sealed package continues to generate substantial residual chemicals such as peroxides that are trapped in that package over the lifetime of the solar cell module. However, the above described present invention, which employs a combination of TPU and EVA, effectively reduces the residual chemicals generated during the lamination process by at least 50% since one of the EVA layers is eliminated. Therefore, in the present invention, the amount of chemicals that are a source of module failure is less than 50% of the prior art modules which are fully sealed with EVA.

Adding to this, another advantage of using EVA at the bottom of the module is that the residual chemicals generated during lamination do not hurt the active part of the solar cells which are located at the front side. Besides, since the EVA is behind the solar cells (where the substrate is) its exposure to sunlight is blocked off by the solar cells on top of the EVA layer. Thus, the EVA layer is not exposed to sunlight and residual chemicals generated as a result of this exposure during the operation are eliminated, except at the edges of the cells which occupy a relatively small area.

Further more, the modulus of elasticity for TPU is higher than that is for EVA (about 4000 PSI for TPU and 1000 PSI for EVA), making TPU a more rigid material than EVA. The solar cells in a module will be exposed to mechanical and thermal stresses in the outdoors as they are heated up by sun during the day and cooled down during the night or when they are exposed to windy situations. Cuddihy et al. (Applications of Ethylene Vinyl Acetate as an Encapsulation Material for Terrestrial Photovoltaic Modules, E. F. Cuddihy. C. D. Coulbert, R. H. Liang, A. Gupta, P. Willis, B. Baum, DOE/JPL/1012-87,) have shown that the encapsulant thickness needed to protect solar cells in a solar module depends on the encapsulant material's modulus of elasticity. The lower the modulus of elasticity, the lesser the thickness of encapsulant required to dampen the stresses on the solar cells inside a solar module. It has been found that the thickness (in units of mils) to modulus of elasticity ratio (in units of klb/inch²) should be equal to or greater than 4 for encapsulant material to dampen the stress due to wind deflection. (E. F. Cuddihy, Encapsulant Selection and Durability Testing Experience, Jet Propulsion Laboratory, Reliability and Eng. of Thin-Film Photovoltaic Modules; p 249-274, 1985) Typically, 12 to 18 mils thickness range is the most commonly used material specification for EVA layers in the solar cell industry. From a t/E ratio point of view, the 18 mil thickness is very well sufficient even for the reduced EVA thickness (˜20%) after lamination. A typical TPU thickness range in the industry may be 20-25 mils. Minimum 20 mil thicknesses is required for TPU encapsulant to be able to dampen the stresses on solar cells taking into considerations of t/E, and reduced encapsulant thickness after lamination. TPU(front encapsulant)/TPU (back encapsulant) packages need to use thicker TPU layers (total ≧40 mils) than the EVA layers in an EVA/EVA packages (˜20-36 mils) to dampen the deflective and thermal stresses in the sealed module structure. Since EVA is less rigid than TPU material, by using a thin and flexible EVA on the bottom of the cell, the overall TPU/EVA package thickness is reduced. 20 mil thick TPU for front and 12 mil thick EVA for the back layer encapsulant, a total of 32 mil, will be sufficient to protect the solar cells from the deflective stresses. This is especially important for flexible module packages. Thinner package has more mechanical flexibility.

Another advantage of using a combination of a TPU layer along with a EVA layer is that this combination can be manufactured using a roll-to-roll process in which the combination TPU/EVA layers are sufficiently flexible to be rolled upon completion, whereas an EVA only construction is too rigid for use in a roll-to-roll process manufacturing.

Although the present invention is described with respect to certain preferred embodiments, modifications thereto will be apparent to those skilled in the art.

We claim:

1. A solar cell module, comprising:
a solar cell device including at least two solar cells, each solar cell including a Group IBIIIAVIA absorber layer and a conductive substrate, wherein the solar cell device comprises a light receiving side having a light receiving surface and a back side having a back surface, the light receiving side of the device comprising the Group IBIIIAVIA absorber layer of each solar cell and the back side comprising the conductive substrate of each solar cell;
a light receiving side encapsulant layer coating the light receiving surface, wherein the light receiving side encapsulant comprises a thermoplastic polyurethane; and
a back side encapsulant layer coating the back surface, wherein the back side encapsulant layer is different from the light receiving side encapsulate layer.

2. The solar cell module of claim 1, wherein the back side encapsulant layer comprises ethylene vinyl acetate copolymer.

3. The solar cell module of claim 1, wherein the back side encapsulant comprises a non-transparent material.

4. The solar cell module of claim 1 further comprising a front protective layer disposed over the light receiving side encapsulant layer.

5. The solar cell module of claim 4, wherein the front protective layer comprises one of glass and ETFE (ethylene tetrafluoroethylene).

6. The solar cell module of claim 4, wherein the back protective layer has a stacked structure comprising sheets of PVF (polyvinyl fluoride) and aluminum.

7. The solar cell module of claim 4, wherein the back protective layer has a stacked structure comprising sheets of PEN (polyethylene naphthalate) and aluminum.

8. The solar cell module of claim 4, wherein the back protective layer has a stacked structure comprising sheets of PET (polyethylene terephthalate) and aluminum.

9. The solar cell module of claim 4, wherein the conductive substrate is stainless steel.

10. The solar cell module of claim 1 further comprising a back protective layer disposed under the back side encapsulant layer.

11. The solar cell module of claim 10, wherein the back protective layer comprises one of glass and PVF (polyvinyl fluoride).

12. The solar cell module of claim 1, wherein the light receiving side encapsulant layer has a thickness range of 20-25 mils.

13. The solar cell module of claim 1, wherein the back side encapsulant layer has a thickness range of 12-18 mils.

14. A method of manufacturing a solar module, comprising:
providing a front protective layer having a front surface and a back surface, wherein the front protective layer is transparent;
placing a light receiving side encapsulant layer over the back surface of the front protective layer, wherein the light receiving side encapsulant comprises thermoplastic polyurethane;
placing a solar cell device over the light receiving side encapsulant layer, wherein the solar cell device includes at least two solar cells, and each solar cell includes a Group IBIIIAVIA absorber layer and a conductive substrate, the solar cell device comprising a light receiving side having a top surface and a back side having a back surface, the light receiving side of the device comprising the Group IBIIIAVIA absorber layer of each solar cell and the back side comprising the conductive substrate of each solar cell, and wherein the top surface of the solar cell device faces the light receiving side encapsulant layer;
placing a back side encapsulant layer over the back surface of the solar cell device, wherein the back side encapsulant layer is different from the light receiving side encapsulant layer;
placing a back protective layer over the back side encapsulant layer, and thereby forming a multilayer structure;
subjecting the multilayer structure heat and pressure to melt the light receiving side encapsulant layer between the front protective layer and the solar light receiving side of the solar cell and back side encapsulant layer between the back side of the solar cell and the back protective layer; and
cooling the multilayer structure to bond the light receiving side encapsulant layer between to the front protective layer and the solar light receiving side of the solar cell, and back side encapsulant layer to the back side of the solar cell and the back protective layer.

15. The method of claim 14, wherein the back side encapsulant layer comprises ethylene vinyl acetate copolymer.

16. The method of claim 14, wherein the step of subjecting the multilayer structure to heat and pressure comprises applying a temperature range of 120° C. to 160° C., a pressure range of 0.5 to 1 atm.

17. The method of claim 14, wherein the front protective layer comprises one of glass and ETFE (ethylene tetrafluoroethylene).

18. The method of claim 14, wherein the back protective layer comprises one of glass and PVF (polyvinyl fluoride).
